(19) United States
(12) Patent Application Publication
(10) Pub. No.: US 2025/0205733 A1
(43) Pub. Date: Jun. 26, 2025

(54) APPARATUS FOR TREATING SUBSTRATE AND VALVE ASSEMBLY USED IN THE SAME

(71) Applicant: SEMES CO., LTD., Cheonan-si (KR)

(72) Inventors: Ju Dong LEE, Cheonan-si (KR); Hyun Jin YANG, Hwaseong-si (KR); Seung Tae YANG, Yongin-si (KR)

(73) Assignee: SEMES CO., LTD., Cheonan-si (KR)

(21) Appl. No.: 18/978,169

(22) Filed: Dec. 12, 2024

(30) Foreign Application Priority Data
Dec. 26, 2023 (KR) 10-2023-0191424

(51) Int. Cl. B05C 11/10; G05D 7/06

(52) U.S. Cl. CPC B05C 11/1026; G05D 7/0635

(57) ABSTRACT

Disclosed is a substrate treating apparatus including a valve assembly. The valve assembly includes a body and a diagram, and the body includes an inlet port through which the treatment liquid is introduced from a liquid supply source side, an outlet port through which the treatment liquid is discharged to the liquid treating chamber side, and a recirculation port through which the treatment liquid returns to the liquid supply source side. The diaphragm opens and closes a flow path of the treatment liquid flowing toward the outlet port side. The treatment liquid introduced into the body of the valve assembly is supplied to a nozzle through the outlet port or recovered to the liquid supply source side through the recirculation port.

### CROSS-REFERENCE TO RELATED APPLICATIONS

This application claims priority to and the benefit of Korean Patent Application No. 10-2023-0191424 filed in the Korean Intellectual Property Office on Dec. 26, 2023, the entire contents of which are incorporated herein by reference.

### TECHNICAL FIELD

The invention relates to an apparatus for treating a substrate, and more specifically, to an apparatus for liquid treating a substrate by supplying a treatment liquid to the substrate, and a valve assembly provided to the apparatus to control whether or not to supply a treatment liquid.

### BACKGROUND ART

In order to manufacture a semiconductor device or a liquid crystal display, various processes, such as photography, etching, ashing, ion implantation, thin film deposition, and cleaning, are performed on a substrate. Among them, in the cleaning process, a treatment liquid is supplied to the substrate to remove thin films or particles on the substrate.

In general, in the cleaning process, the nozzle supplies the treatment liquid from the top of the substrate.

The treatment liquid may be chemical, pure water, an organic solvent, or the like. An apparatus for performing a cleaning process has a nozzle and a liquid supply line for supplying a treatment liquid to the nozzle, and a valve for opening and closing a flow path is generally provided in the liquid supply line.

FIG. 1 is a cross-sectional view schematically illustrating a structure of a commonly used valve. Referring to FIG. 1, the valve has a body in which a buffer space is formed, and an inflow path through which a treatment liquid is introduced and an outflow path through which a treatment liquid is discharged are formed in the buffer space. The inflow path and the outflow path are connected to the buffer space, and a diaphragm for opening and closing the outflow path is disposed in the buffer space. In the above structure, when the diaphragm closes the outflow path, a treatment liquid remains in the buffer space.

In particular, in the structure illustrated in FIG. 1, the treatment liquid flowing to the inflow path flows divided into opposite sides of the diaphragm in the buffer space. Therefore, as illustrated in FIG. 2, since the treatment liquid forms a vortex due to collision in an area opposite to the area to which the inflow path is connected, the amount of particles generated is larger.

When the treatment liquid remains in the buffer space for a long time, particles are generated from the treatment liquid. When the diaphragm opens the outflow path and supplies the treatment liquid to the substrate, particles remaining in the buffer space are supplied to the substrate together with the treatment liquid.

### SUMMARY OF THE INVENTION

The present invention has been made in an effort to provide a valve assembly capable of minimizing discharge of a treatment liquid containing particles to a substrate when treating a substrate, and a substrate treating apparatus including the same.

The present invention has also been made in an effort to provide a valve assembly capable of solving the problem of generating particles from a treatment liquid remaining in a valve when the valve is closed, and a substrate treating apparatus including the same.

The problem to be solved by the present invention is not limited to the above-mentioned problems, and the problems not mentioned will be clearly understood by those skilled in the art from the descriptions below.

An exemplary embodiment of the present invention provides an apparatus for treating a substrate, the apparatus comprising: a liquid treating chamber formed with a treatment space in which a treatment liquid is supplied onto a substrate to liquid-treat the substrate; and a liquid supply unit for supplying the treatment liquid to the liquid treating chamber, wherein the liquid supply unit includes: a liquid supply line through which the treatment liquid flows; and a valve assembly installed in the liquid supply line, and the valve assembly includes: a body including an inlet port through which the treatment liquid is introduced from a liquid supply source side, an outlet port through which the treatment liquid is discharged to the liquid treating chamber side, and a recirculation port through which the treatment liquid returns to the liquid supply source side; and a diaphragm provided to the body and opening and closing a flow path of the treatment liquid flowing toward the outlet port side.

According to the example, the body may be formed with: a buffer space; an inflow path connecting the inlet port and the buffer space; an outflow path connecting the buffer space and the outlet port; and a recirculation path connecting the buffer space and the recirculation port therein.

According to the example, the valve assembly may further include a driver for moving the diaphragm between an open position for opening the outflow path and a closed position for closing the outflow path, and when the diaphragm is in the closed position, the diaphragm may be located in the buffer space.

According to the example, the buffer space is defined by an inner wall, a bottom wall, and an upper wall, and when the diaphragm is in the closed position, the diaphragm may be located to be spaced apart from the inner wall.

According to the example, the buffer space is provided in a cylindrical shape, and a central axis of the buffer space and a central axis of the diaphragm may coincide with each other.

According to the example, an inlet of the outflow path may be located in the bottom wall.

According to the example, an outlet of the inflow path and an inlet of the recirculation path may be each located at the inner wall.

According to the example, an outlet of the inflow path and an inlet of the recirculation path may be each located at the inner wall.

According to the example, when viewed from above, the outlet of the inflow path, an inlet of the outflow path, and the inlet of the recirculation path may be sequentially arranged in a straight line.

According to the example, the liquid supply source includes a supply tank in which the treatment liquid is stored, the liquid supply line includes: a first line connecting the liquid supply source to the inlet port of the valve assembly; a second line connecting the outlet port of the valve assembly to the liquid treating chamber, and the recirculation port and the supply tank may be connected by a recirculation line.

According to the example, an opening/closing valve may be installed on the recirculation line.

According to the example, the valve assembly is further formed with a suction space directly communicating with the outflow path, and the valve assembly further includes a suction plate that adjusts a volume of the suction space.

According to another example, the substrate treating apparatus further includes a controller controlling the driver and the opening/closing valve. A diaphragm position in a state in which the diaphragm is raised and the outflow path is opened will be referred to as an open position, and a diaphragm position in a state in which the diaphragm is lowered and the outflow path is closed will be referred to as a closed position. The controller may control the driver and the opening/closing valve to open the opening/closing valve when the diaphragm is in the closed position, and to close the opening/closing valve when the diaphragm is in the open position.

Another exemplary embodiment of the present invention provides a valve assembly comprising: a body including: an inlet port through which a treatment fluid is introduced from a liquid supply source side; an outlet port through which a treatment fluid is discharged toward a liquid treating chamber side; and a body including a recirculation port for returning the treatment liquid toward the liquid supply source side; and a diaphragm provided to the body and opening and closing a flow path of the treatment liquid flowing toward the outlet port side.

According to the example, a buffer space, an inflow path, an outflow path, and a recirculation path are formed in the body, and the diaphragm moves between an open position for opening the outflow path and a closed position for closing the outflow path. When the diaphragm is in the closed position, the diaphragm is located in the buffer space. When the diaphragm is in the closed position, the diaphragm is located to be spaced apart from the inner wall.

According to the example, an outlet of the inflow path and an inlet of the recirculation path may be each located at the inner wall.

According to the example, when viewed from above, the outlet of the inflow path, an inlet of the outflow path, and the inlet of the recirculation path may be sequentially arranged in a straight line.

According to another example, an outlet of the inflow path and an inlet of the recirculation path may be each located in the bottom wall.

According to the example, when viewed from above, the outlet of the inflow path, an inlet of the outflow path, and the inlet of the recirculation path may be sequentially arranged in a straight line.

Still another exemplary embodiment of the present invention provides an apparatus for treating a substrate, the apparatus comprising: a liquid treating chamber having a treatment space in which a treatment liquid is supplied onto a substrate to liquid-treat the substrate; and a liquid supply unit for supplying the treatment liquid to the liquid treating chamber, wherein the liquid supply unit includes: a supply tank in which the treatment liquid is stored; a liquid supply line through which the treatment liquid in the supply tank flows into a liquid treating chamber; and a valve assembly installed in the liquid supply line, and the valve assembly includes: a body including an inlet port through which the treatment fluid is introduced from a liquid supply source side, an outlet port through which the treatment liquid is discharged toward the liquid treating chamber side, and a recirculation port which returns the treatment liquid to the liquid supply source side, and a buffer space, and formed with an inflow path connecting the inlet port and the buffer space, an outflow path connecting the buffer space and the outlet port, and a recirculation path connecting the buffer space and the recirculation port; a diaphragm located in the buffer space and opening and closing an inlet of the outflow path; and a driver that moves the diaphragm between an open position that opens the inlet of the outflow path and a closed position that closes the inlet of the outflow path, the buffer space is defined by an inner wall, a bottom wall, and an upper wall, and when the diaphragm is in the closed position, the diaphragm is located in the buffer space to be spaced apart from the inner wall, the recirculation port and the supply tank are connected by a recirculation line, and an opening/closing valve may be installed on the recirculation line.

According to the exemplary embodiment of the present invention, when the treatment liquid is discharged to the substrate through the liquid supply line in which the valve is installed, the discharge of the treatment liquid containing particles to the substrate may be minimized.

In addition, according to the exemplary embodiment of the present invention, particles may be prevented from being generated due to the residual treatment liquid in the valve when the valve is closed.

The effect of the present invention is not limited to the foregoing effects, and the not-mentioned effects will be clearly understood by those skilled in the art from the present specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a cross-sectional view schematically illustrating a cross-section of a general valve assembly.

FIG. 2 is a top plan view of a general valve assembly.

FIG. 3 is a top plan view of a substrate treating apparatus according to an exemplary embodiment of the present invention.

FIG. 4 is a cross-sectional view schematically illustrating a structure of a liquid treating chamber in FIG. 3.

FIG. 5 is a diagram schematically illustrating the configuration of a liquid supply unit according to the exemplary embodiment of the present invention.

FIG. 6 is a cross-sectional view schematically illustrating an exemplary embodiment of a valve assembly of FIG. 5.

FIG. 7 is a top plan view illustrating the configuration of the valve assembly of FIG. 6.

FIG. 8 is a diagram schematically illustrating a flow of a treatment liquid in an open position of the valve assembly of FIG. 6.

FIG. 9 is a diagram schematically illustrating the flow of a treatment liquid in a closed position of the valve assembly of FIG. 6.

FIGS. 10 to 14 are cross-sectional views schematically illustrating a modified example of the valve assembly of FIG. 6, respectively.

FIG. 15 is a diagram schematically illustrating a modified example of the liquid supply unit of FIG. 5.

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In addition, in describing an exemplary embodiment of the present invention in detail, if it is determined that a detailed description of a related well-known function or configuration may unnecessarily obscure the gist of the present invention, the detailed description thereof will be omitted. In addition, the same reference numerals are used throughout the drawings for parts having similar functions and actions.

In addition, unless explicitly described to the contrary, the word “comprise” and variations such as “comprises” or “comprising” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

An expression, “and/or” includes each of the mentioned items and all of the combinations including one or more of the items. Further, in the present specification, “connected” means not only when member A and member B are directly connected, but also when member A and member B are indirectly connected by interposing member C between member A and member B.

The exemplary embodiment of the present invention may be modified in various forms, and the scope of the present invention should not be construed as being limited to the following exemplary embodiments. The present exemplary embodiment is provided to more completely explain the present invention to those skilled in the art. Therefore, the shapes of elements in the drawings are exaggerated to emphasize clearer descriptions.

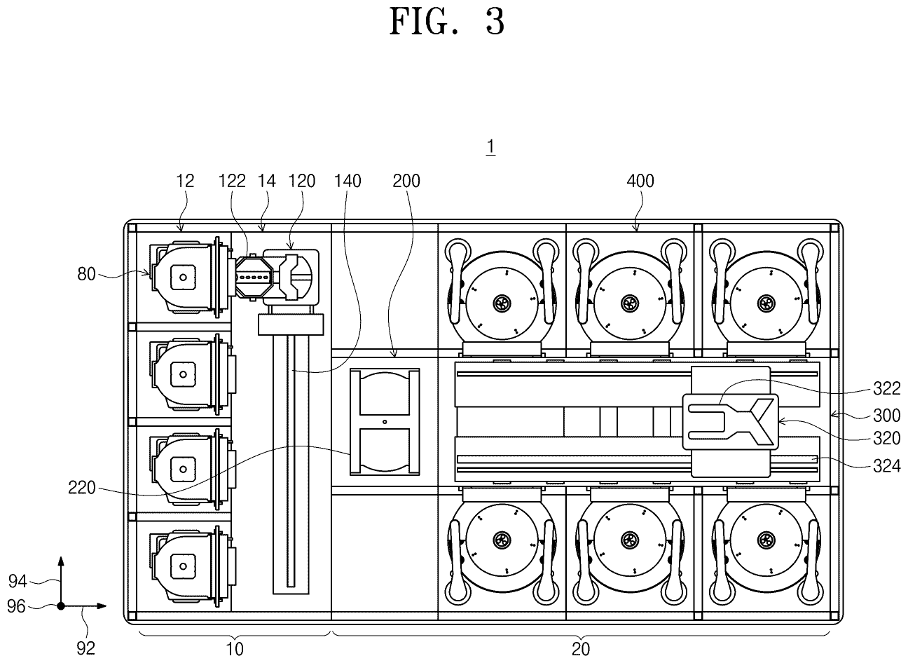

FIG. 3 is a top plan view of a substrate treating apparatus according to an exemplary embodiment of the present invention.

In the following, the substrate may be a wafer or mask used to manufacture a semiconductor, or a substrate used to manufacture a panel for a display.

Referring to FIG. 3, a substrate treating system includes an index module 10, a treating module 20, and a controller (not illustrated). According to the exemplary embodiment, the index module 10 and the treating module 20 are disposed along one direction. Hereinafter, the direction in which the index module 10 and the treating module 20 are disposed is referred to as a first direction 92, and when viewed from above, a direction vertical to the first direction 92 is referred to as a second direction 94, and a direction perpendicular to both the first direction 92 and the second direction 94 is referred to as a third direction 96.

The index module 10 transfers a substrate W from a container 80 in which the substrate W is accommodated to the treating module 20, and makes the substrate W, which has been completely treated in the treating module 20, be accommodated in the container 80. A longitudinal direction of the index module 10 is provided in the second direction 94. The index module 10 includes a load port 12 and an index frame 14. Based on the index frame 14, the load port 12 is located at a side opposite to the treating module 20. The containers 80 in which the substrates W are accommodated are placed on the load ports 12. The load port 12 may be provided in plurality, and the plurality of load ports 12 may be disposed in the second direction 94.

An index robot 120 is provided to the index frame 14. A guide rail 140 of which a longitudinal is the second direction 94 is provided within the index frame 14, and the index robot 120 may be provided to be movable on the guide rail 140. The index robot 120 includes a hand 122 on which the substrate W is placed, and the hand 122 may be provided to be movable forwardly and backwardly, rotatable around the third direction 96, and be movable along the third direction 96. The plurality of hands 122 is provided while being spaced apart from each other in the vertical direction, and is capable of independently moving forward and backward.

The treating module 20 includes a buffer unit 200, a transfer chamber 300, and a liquid treating chamber 400. The buffer unit 200 provides a space in which the substrate W loaded into the treating module 20 and the substrate W unloaded from the treating module 20 stay temporarily. The liquid treating chamber 400 performs a liquid treatment process for liquid-treating the substrate W by supplying a liquid onto the substrate W. The liquid treating chamber 400 performs a drying process for removing the liquid remaining on the substrate W. The transfer chamber 300 transfers the substrate W between the buffer unit 200 and the liquid treating chamber 400.

The transfer chamber 300 may be provided so that a longitudinal direction is the first direction 92. The buffer unit 200 may be disposed between the index module 10 and the transfer chamber 300. A plurality of liquid treating chambers 400 is provided and may be disposed on the side of the transfer chamber 300. The liquid treating chamber 400 and the transfer chamber 300 may be disposed in the second direction 94. The buffer unit 200 may be located at one end of the transfer chamber 300.

According to the example, the liquid treating chambers 400 are respectively disposed on both sides of the transfer chamber 300. At each of both sides of the transfer device 300, the liquid treating devices 400 may be provided in an array of A×B (each of A and B is 1 or a natural number larger than 1) in the first direction 92 and the third direction 96.

The transfer chamber 300 includes a transfer robot 320. A guide rail 340 having a longitudinal direction in the first direction 92 is provided in the transfer chamber 300, and the transfer robot 320 may be provided to be movable on the guide rail 340. The transfer robot 320 includes a hand 322 in which the substrate W is placed, and the hand 322 may be provided to be movable forwardly and backwardly, rotatable about the third direction 96, and movable along the third direction 96. A plurality of hands 322 are provided to be spaced apart in the vertical direction, and the hands 322 may move forward and backward independently of each other.

The buffer unit 200 includes a plurality of buffers 220 on which the substrate W is placed. The buffers 220 may be disposed while being spaced apart from each other in the third direction 96. A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

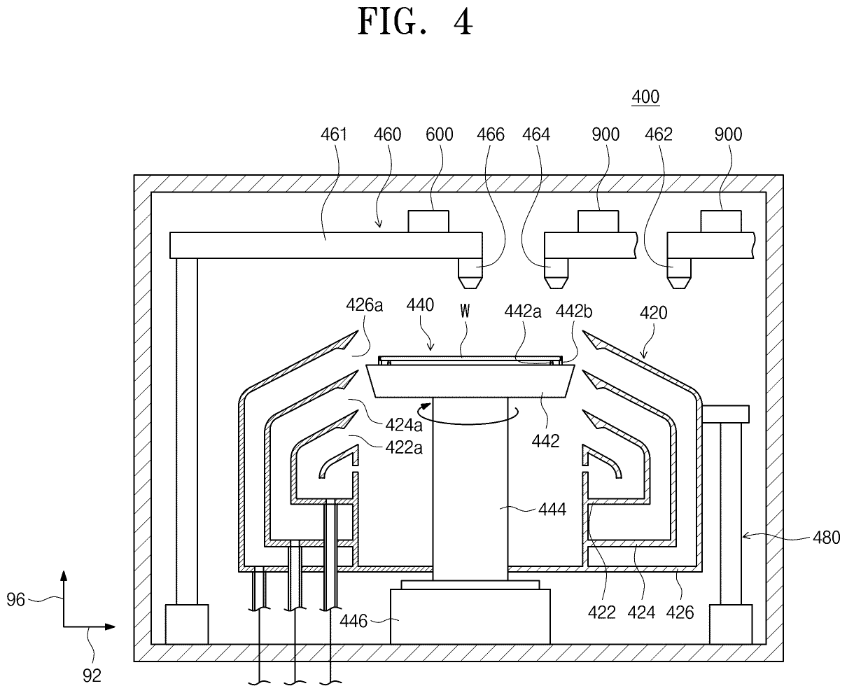

FIG. 4 is a cross-sectional view schematically illustrating a structure of the liquid treating chamber in FIG. 3.

Referring to FIG. 4, the liquid treating chamber 400 includes a housing 410, a cup 420, a support unit 440, a nozzle unit 460, and a lifting unit 480. The housing 410 is provided in a generally rectangular parallelepiped shape. The cup 420, the support unit 440, and the nozzle unit 460 are disposed within the housing 410.

The cup 420 has a treatment space with an open top, and the substrate W is liquid-treated in the treatment space. The support unit 440 supports the substrate W in the treatment space. The nozzle unit 460 supplies a liquid onto the substrate W supported on the support unit 440. The liquid may be provided in a plurality of types, and may be sequentially supplied onto the substrate W. The lifting unit 480 adjusts a relative height between the cup 420 and the support unit 440.

The cup 420 includes a plurality of recovery containers 422, 424, and 426. Each of the recovery containers 422, 424, and 426 has a recovery space of recovering the liquid used for the treatment of the substrate. Each of the recovery containers 422, 424, and 426 is provided in a ring shape surrounding the support unit 440. During the liquid treatment process, the pre-treatment liquid scattered by rotation of the substrate W flows into the recovery space through the inlets 422a, 424a, and 426a of the recovery containers 422, 424, and 426, respectively. According to the exemplary embodiment, the cup 420 includes a first recovery container 422, a second recovery container 424, and a third recovery container 426. The first recovery container 422 is disposed to surround the support unit 440, the second recovery container 424 is disposed to surround the first recovery container 422, and the third recovery container 426 is disposed to surround the second recovery container 424. A second inlet 424a, which introduces the liquid into the second recovery container 424, may be positioned above a first inlet 422a, which introduces the liquid into the first recovery container 422, and a third inlet 426a, which introduces the liquid into the third recovery container 426, may be positioned above the second inlet 424a.

The support unit 440 includes a support plate 442 and a driving shaft 444. An upper surface of the support plate 442 may be provided in a generally circular shape, and may have a diameter larger than a diameter of the substrate W. A support pin 442a supporting the rear surface of the substrate W is provided in the center of the support plate 442, and the upper end of the support pin 442a is provided to protrude from the support plate 442 so that the substrate W is spaced apart from the support plate 442 by a predetermined distance. A chuck pin 442b is provided to an edge of the support plate 442. The chuck pin 442b is provided to protrude upward from the support plate 442, and supports the lateral portion of the substrate W so that the substrate W is not separated from the support unit 440 when the substrate W is rotated. A drive shaft 444 is driven by a driver 446, is connected to the center of the bottom surface of the substrate W, and rotates the support plate 442 with respect to the central axis thereof.

The nozzle unit 460 includes a first nozzle 462, a second nozzle 464, and a third nozzle 466. The first nozzle 462 supplies a first liquid onto the substrate W. The first liquid may be the liquid of removing a film or foreign substances residual on the substrate W. For example, the first liquid may be an acid component chemical, such as sulfuric acid, hydrofluoric acid, phosphoric acid, or hydrochloric acid, an alkali component chemical, such as ammonia, or a mixture of acid or alkali. The second nozzle 464 supplies a second liquid onto the substrate W. The second liquid is water. The third nozzle 466 supplies a third liquid onto the substrate W. According to the exemplary embodiment, the third liquid may be an organic solvent. The organic solvent may be isopropyl alcohol (IPA). The first nozzle 462, the second nozzle 464, and the third nozzle 466 are supported by different arms 461, and these arms 461 may be moved independently. Optionally, the first nozzle 462, the second nozzle 464, and the third nozzle 466 may be mounted on the same arm 461 and moved simultaneously.

The lifting unit 480 moves the cup 420 in the up and down direction. By the up and down movement of the cup 420, a relative height between the cup 420 and the substrate W is changed. Through this, the recovery containers 422, 424, and 426 to which pre-treatment liquids are recovered are changed according to the type of liquid supplied to the substrate W, so that it is possible to separate and recover the liquids. Unlike the description, the cup 420 may be fixedly installed, and the lifting unit 480 may move the support unit 440 in the vertical direction.

The liquid supply unit 490 supplies the treatment liquid to the nozzle unit 460. Hereinafter, the present invention will be described based on the case where the treatment liquid is chemical, and the chemical is supplied to the first nozzle 462 of the nozzle units 460 as an example. For example, the chemical may be a liquid containing sulfuric acid or hydrofluoric acid. Hereinafter, the nozzle unit 460 of the liquid treating chamber 400 will be referred to as a nozzle 460.

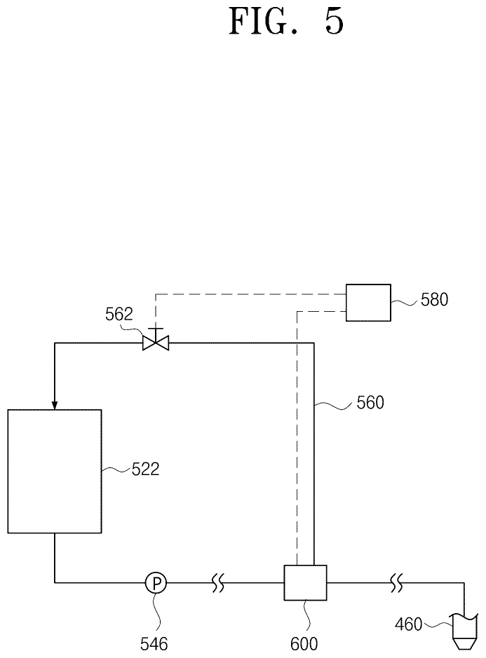

FIG. 5 is a diagram schematically illustrating the configuration of the liquid supply unit supplying the treatment liquid to the nozzle of the liquid treating chamber according to the exemplary embodiment of the present invention.

Referring to FIG. 5, the liquid supply unit 500 includes a liquid supply source 520, a liquid supply line 540, a valve assembly 600, a recirculation line 560, and a controller 580. The liquid supply source 520 stores a treatment liquid supplied to the liquid treating chamber 400. The liquid supply source 520 includes a supply tank 522. The supply tank 522 may have a cylindrical shape. A space in which a treatment liquid is stored is formed inside the supply tank 522.

The liquid supply line 540 supplies the treatment liquid in the liquid supply source to the nozzle 460 of the liquid treating chamber 400. The liquid supply line 540 connects the supply tank 522 to the nozzle 460. The valve assembly 600 is installed in the liquid supply line 540. The liquid supply line 540 includes a first line 542 and a second line 544. A pump 546 is installed in the first line 542. The pump 546 provides the flow pressure so that the treatment liquid flows from the supply tank 522 to the nozzle 460. Also, a flow meter 548 or a static pressure valve 550 may be installed in the first line 542. Also, other components, such as a filter 552, a heater 554, and various types of valves, may be selectively installed in the first line 542 and the second line 544. The filter 552 removes foreign substances from the treatment liquid flowing through the liquid supply line 540. The heater 554 heats the treatment liquid in the liquid supply line 540 to a temperature suitable for treating a substrate.

The recirculation line 560 is provided to selectively recirculate the treatment liquid in the valve assembly 600 into the supply tank 522. An opening/closing valve 562 is installed in the recirculation line 560.

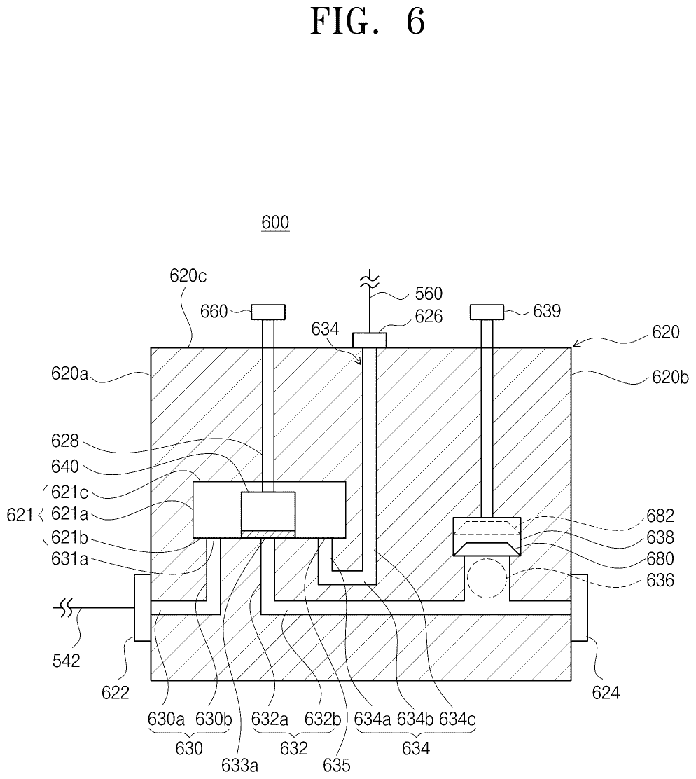

FIG. 6 is a cross-sectional view schematically illustrating an internal structure of the valve assembly.

FIG. 6 schematically illustrates positions of a buffer space 621, an inflow path 630, an outflow path 632, and a recirculation path 634 in the valve assembly of FIG. 5. Referring to FIG. 6, the valve assembly 600 includes a body 620, a diaphragm 640, and a driver 660. The body 620 includes an inlet port 622, an outlet port 624, and a recirculation port 626. The first line 542 of the liquid supply line 540 is connected to the inlet port 622. A second line 544 of the liquid supply line 540 is connected to the outlet port 624. The recirculation line 560 is connected to the recirculation port 626.

The buffer space 621, an inflow path 622, an outflow path 624, and a recirculation path 626 are formed inside the body 620. The buffer space 621 may be provided as a cylinder inside the body 620. The buffer space 621 is defined by an inner wall 621a, a bottom wall 621b, and an upper wall 621c. The bottom wall 621b and the upper wall 621c are provided in a circular shape, and the inner wall 621a is provided in a ring shape.

According to the exemplary embodiment, the inflow path 630, the outflow path 632, and the recirculation path 634 communicate with the buffer space 621. The inflow path 630 connects the inlet port 622 to the buffer space 621. The outflow path 632 connects the outlet port 624 to the buffer space 621. The recirculation path 634 connects the recirculation port 626 to the buffer space 621.

A suction space 636 may be formed in the body 620. The suction space 636 is provided to directly communicate with the outflow path 632. A suction plate 638 is provided in the suction space 636. The suction plate 638 is provided to be movable in a vertical direction in the suction space 636 by a suction driver 639. The suction plate 638 is moved between a first position 638a and a second position 638b. When the suction plate 638 is moved from the first position 638a to the second position 638b, the volume of a region of the suction space 636 that is directly communicated with the outflow path 632 is increased. When the suction plate 638 is moved from the second position 638b to the first position 638a, the volume of a region of the suction space 636 that is directly communicated with the outflow path 632 is decreased. Immediately after the supply of the treatment liquid to the nozzle 460 is stopped, the volume B of a region of the suction space 636 that is directly communicated with the outflow path 632 is increased. Accordingly, the treatment liquid present at the end of the nozzle 460 is moved to the inner space of the nozzle 460 by a predetermined distance

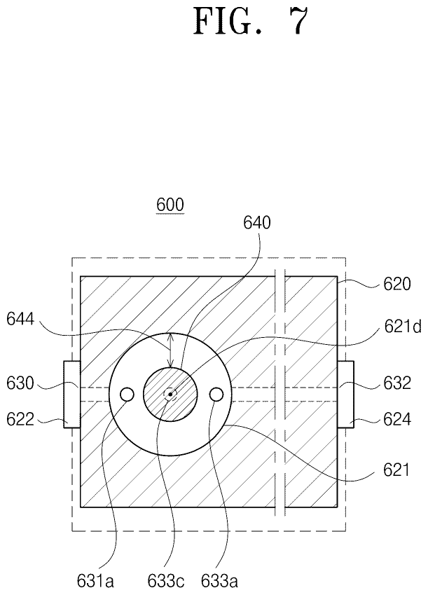

FIG. 7 is a top plan view illustrating the configuration of the valve assembly.

Referring to FIGS. 6 and 7, the inlet 633a of the outflow path 632 is formed at the bottom wall 621b of the buffer space 621. The inlet 633 of the outflow path 632 may be located at a central portion of the bottom wall 621b. The outlet 631a of the inflow path 630 is formed at the bottom wall 621b of the buffer space 621. Also, the inlet 635 of the recirculation path 634 is formed at the bottom wall 621b of the buffer space 621. The outlet 631a of the inflow path 630 and the inlet 635 of the recirculation path 634 may be located at the same distance from the inlet 633 of the outflow path 632. When viewed from above, the outlet 631a of the inflow path 630, the inlet 633 of the outflow path 632, and the inlet 635 of the recirculation path 634 may be located on a straight line.

The inflow path 630 has a first portion 630a and a second portion 630b. The first portion 630a is located adjacent to the inlet port 622. The outlet 631a of the inflow path 630 is provided on the second portion 630b. The inlet port 622 is provided on a first side surface 620a of the body 620. The first portion 630a is provided in a direction perpendicular to the first side surface 620a of the body 620. The second portion 630b extends from the first portion 630a. The second portion 630b is provided in a direction perpendicular to the first portion 630a. A longitudinal direction of the second portion 630b may be provided in a vertical direction.

The outflow path 632 has a first portion 632a and a second portion 632b. The inlet 633 of the outflow path 632 is provided on the first portion 632a. The second portion 632b is located adjacent to the outlet port 624. A longitudinal direction of the first portion 632a may be provided in a vertical direction. The second portion 632b extends from the first portion 632a. The second portion 632b is provided in a direction perpendicular to the first portion 632a. The outlet port 624 is provided on a second side surface 620b of the body 620. The second portion 632b may be provided in a direction perpendicular to the second side surface 620b.

The recirculation path 634 has a first portion 634a, a second portion 634b, and a third portion 634c. The inlet 635 of the recirculation path 634 is provided on the first portion 634a. The third portion 634c is located adjacent to the recirculation port 626. The second portion 634b extends from the first portion 634a to the third portion 634c. A longitudinal direction of the first portion 634a may be provided in a vertical direction. The first portion 634a may be provided in a vertical direction with respect to the first portion 634a. The recirculation port 626 is provided on a third side surface 620c of the body 620. The third side surface 620c may be a top surface of the body 620. The third portion 634c may be provided in a direction perpendicular to the third side surface 620c. The first portion 634a and the third portion 634c may be provided parallel to each other, and the second portion 634b may be provided perpendicular to the first portion 634a and the third portion 634c.

The controller 580 controls the opening/closing valve 562 and the valve assembly 600 installed in the recirculation line 560.

Referring to FIG. 7, the diaphragm 640 opens and closes the inlet 633 of the outflow path 632 by the controller 580. The diaphragm 640 may be formed of an elastic material. The diaphragm 640 is positioned within the buffer space 621. When viewed from above, the diaphragm 640 is disposed to overlap the inlet 633 of the outflow path 632. The diaphragm 640 has an area larger than the inlet 633 of the outflow path 632. When viewed from above, the diaphragm 640 has an area narrower than the buffer space 621. A central axis 642 of the diaphragm 640 may be provided to coincide with a central axis 621d of the buffer space 621. Also, the central axis 642 of the diaphragm 640 may be provided to coincide with a central axis 633c of the inlet 633 of the outflow path 632. Accordingly, the diaphragm 640 is positioned to be spaced apart from the inner wall 621a, which forms the buffer space 621. In the buffer space 621, a gap 644 through which a fluid flows is formed around the diaphragm 640. The gap 644 between the inner wall 621a of the buffer space 621 and the diaphragm 640 may be provided to be the same along the circumferential direction of the diaphragm 640.

The diaphragm 640 is provided to be movable between an open position and a closed position. The open position is a position of the diaphragm 640 for opening the inlet 633 of the outflow path 632. The closed position is a position of the diaphragm 640 for closing the inlet 633 of the outflow path 632. When the diaphragm 640 is in the open position, the diaphragm 640 may be located in an upper area within the buffer space 621. In the open position, the diaphragm 640 is spaced apart from the inlet 633a of the outflow path 632. When the diaphragm 640 is in the closed position, the diaphragm 640 is located in the lower end area within the buffer space 621. In the closed position, the diaphragm 640 is in close contact with the inlet 633a of the outflow path 632. The position of the diaphragm 640 may be changed between the open position and the closed position by the vertical movement.

The driver 660 moves the diaphragm 640 between the open position and the closed position. According to the example, a plunger 628 is positioned on the body 620. The diaphragm 640 is attached to the lower end of the plunger 628. The plunger 628 has a rod shape. The plunger 628 may have a longitudinal direction provided in a vertical direction. The driver 660 moves the plunger 628 along the longitudinal direction thereof. The driver 660 may move the plunger 628 by an electronic or pneumatic method.

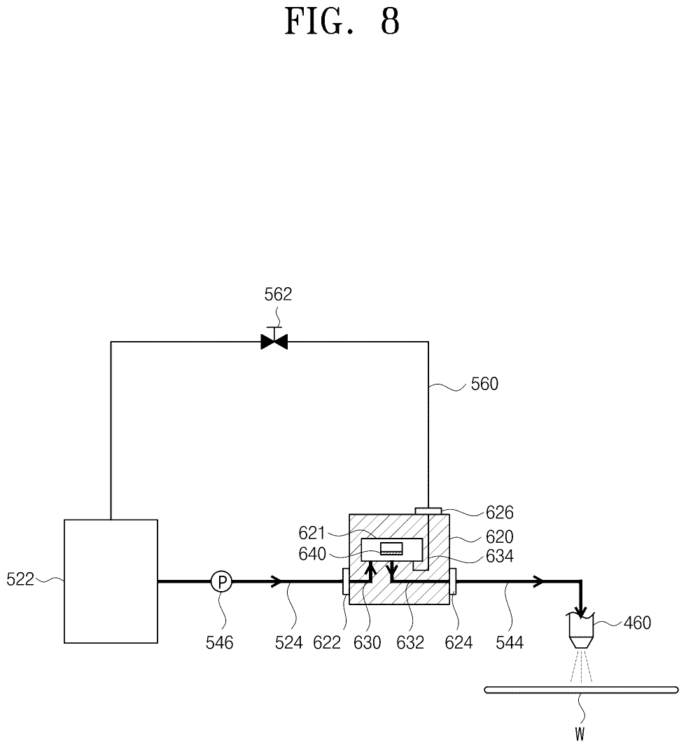

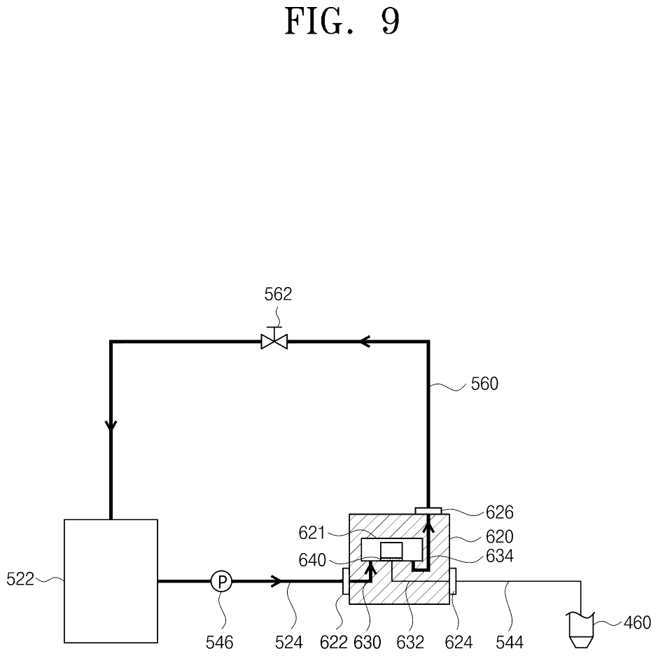

FIGS. 8 and 9 are diagrams illustrating an operation state of the valve assembly of FIG. 6 and a flow of the treatment liquid, respectively. FIG. 8 is a diagram schematically illustrating a flow of the treatment liquid when the diagram in the valve assembly is in the open position, and FIG. 9 is a diagram schematically illustrating a flow of the treatment liquid when the diagram in the valve assembly is in the closed position.

Referring to FIG. 8, when the diaphragm 640 is in the open position, the opening/closing valve 562 provided to the recirculation line 560 is closed. A treatment liquid flows from the supply tank 522 along the first line 542 by the operation of the pump 546. The treatment liquid flows into the valve assembly 600 through the port 622. The treatment liquid flows sequentially along the inflow path 630, the buffer space 621, and the outflow path 632. Thereafter, the treatment liquid flows out from the valve assembly 600 through the outlet port 624, and is supplied to the nozzle 460 through the second line 544. The nozzle 460 discharges the treatment liquid to the substrate W.

When the supply of the treatment liquid to the substrate W is completed, the supply of the treatment liquid to the nozzle 460 is stopped.

Referring to FIGS. 6 and 9, the diaphragm 640 is moved from the open position to the closed position, and along with this, the opening/closing valve 562 provided in the recirculation line 560 is opened. The treatment liquid flows from the supply tank 522 along the first line 542 by the operation of the pump 546. The treatment liquid flows into the valve assembly 600 through the port 622. The treatment liquid flows sequentially along the inflow path 630, the buffer space 621, and the recirculation path 634. Thereafter, the treatment liquid is discharged from the valve assembly 600 through the recirculation port 626 and is recovered back to the supply tank 522 through the recirculation line 560.

After the diaphragm 640 is moved from the open position to the closed position, the suction plate 638 is moved from a first position 680 to a second position 682. Accordingly, the treatment liquid at the end of the nozzle 460 is moved to the inside of the nozzle 460 by a predetermined distance.

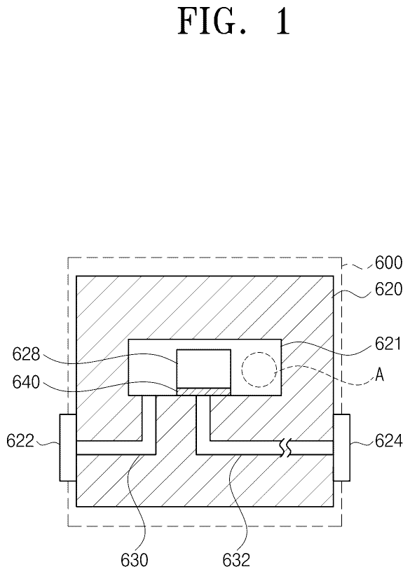

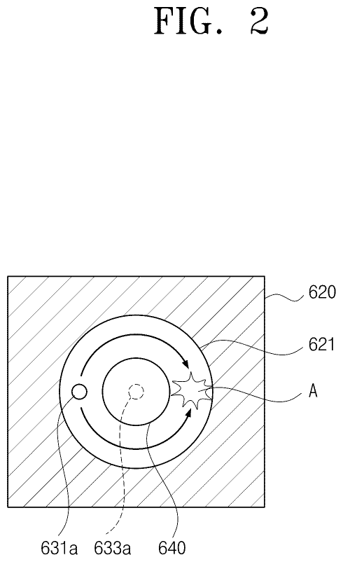

In the valve assembly 600 having the structure as illustrated in FIG. 1, when the diaphragm 640 is in the closed position, the treatment liquid remains in the buffer space 621. When the treatment liquid remains in the buffer space for a long time and the treatment liquid stagnates (A), a large amount of particles are generated. However, in the valve assembly 600 having the structure as illustrated in FIG. 8, even while the diaphragm 640 is in the closed position, the treatment liquid continuously flows through the supply tank 522, the first line 542, the valve assembly 600, and the recirculation line 560. Therefore, it is possible to prevent particles from being generated due to the residual of the treatment liquid in the buffer space 621.

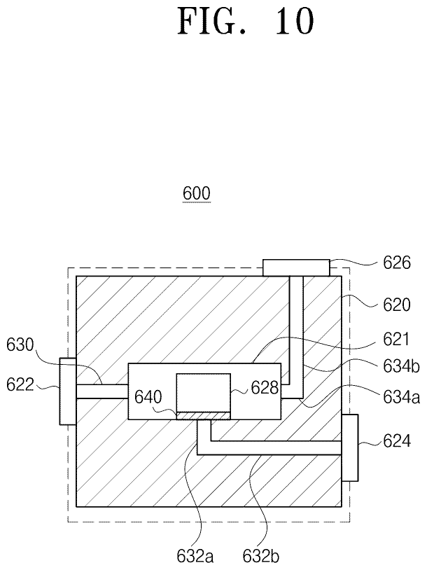

FIG. 10 is a diagram illustrating another example of the valve assembly of FIG. 6.

Referring to FIG. 9, the inlet 633 of the outflow path 632 is formed at the bottom wall 621b of the buffer space 621. The inlet 633 of the outflow path 632 may be located at a central portion of the bottom wall 621b. The outlet 631a of the inflow path 630 is formed at the inner wall 621a of the buffer space 621. Also, the inlet 635 of the recirculation path 634 is formed at the inner wall 621a of the buffer space 621. When viewed from above, the outlet 631a of the inflow path 630, the inlet 633a of the outflow path 632, and the inlet 635 of the recirculation path 634 may be sequentially positioned in a straight line.

The inflow path 630 is provided in a straight line. The inlet 631b of the inflow path 630 is provided at the inlet port 622. The inlet port 622 is provided on a first side surface 620a of the body 620. The outlet 631a of the inflow path 630 is provided at the inner wall 621a of the buffer space 621. The inflow path 630 may be provided perpendicular to the first side surface 620a of the body 620 and the inner wall 621a of the buffer space 621, respectively.

The outflow path 632 may have the same structure as the outflow path 632 in the exemplary embodiment of FIG. 6.

The recirculation path 634 has a first portion 634a and a second portion 634b. The inlet 635 of the recirculation path 634 is provided on the first portion 634a. The second portion 634b is located adjacent to the recirculation port 626. The first portion 634a may be provided in a direction in which a longitudinal direction thereof is perpendicular to a vertical direction. The recirculation port 626 is provided on a third side surface 620c of the body 620. The third side surface 620c may be a top wall of the body 620. The second portion 634b may be provided in a direction perpendicular to the third side surface 620c. The first portion 634a and the second portion 634b may be provided perpendicular to each other.

FIG. 10 is a diagram illustrating another example of the valve assembly of FIG. 6.

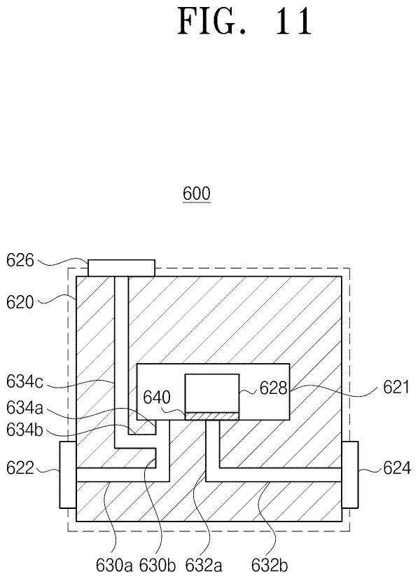

Referring to FIG. 11, the inlet 633a of the outflow path 632 is formed at the bottom wall 621b of the buffer space 621. The outlet 633b of the outflow path 632 may be located at a central portion of the bottom wall 621b. The outlet 633a of the inflow path 632 is formed at the bottom wall 621b of the buffer space 621. The inlet 635 of the recirculation path 634 may be directly connected to the inflow path 630.

The inflow path 630 has a first portion 630a and a second portion 630b. The first portion 630a is located adjacent to the inlet port 622. The outlet 631a of the inflow path 630 is provided on the second portion 630b. The inlet port 622 is provided on a first side surface 620a of the body 620. The first portion 630a is provided in a direction perpendicular to the first side surface 620a of the body 620. A longitudinal direction of the second portion 630b may be provided in a vertical direction.

The outflow path 632 may have the same structure as the outflow path 632 in the exemplary embodiment of FIG. 6.

The recirculation path 634 has a first portion 634a and a second portion 634b. According to the exemplary embodiment, the inlet 635 of the recirculation path 634 is provided in the second portion 630b of the inflow path 630. The first portion 634a of the recirculation path 634 may be provided in the direction perpendicular to the second portion 634b of the inflow path 630. The first portion 634a of the recirculation path 634 may be provided parallel to the first portion 630a of the inflow path 630. The recirculation port 626 is provided on a third side surface 620c of the body 620. The third side surface 620c may be a top wall of the body 620. The second portion 634b may be provided in a direction perpendicular to the third side surface 620c of the body 620. The first portion 634a and the second portion 634b may be provided perpendicular to each other.

Next, various modified examples of the present invention are described.

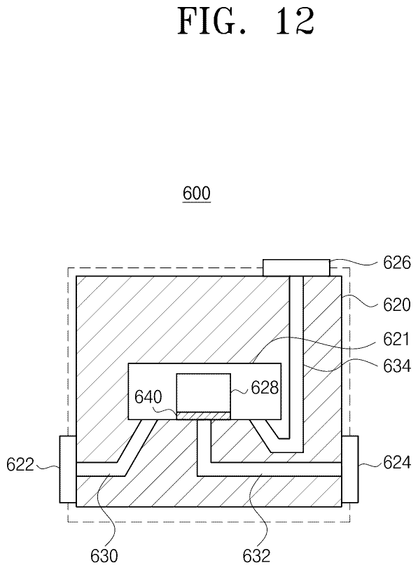

In FIG. 6, the present invention has been described as the portions of the inflow path 630 and the recirculation path 634 directly connected to the buffer space 621 are provided in the vertical direction. However, unlike this, as illustrated in FIG. 12, the portions of the inflow path 630 and the recirculation path 634 directly connected to the buffer space 621 may be provided in a direction inclined with respect to the central axis 621d of the buffer space 621.

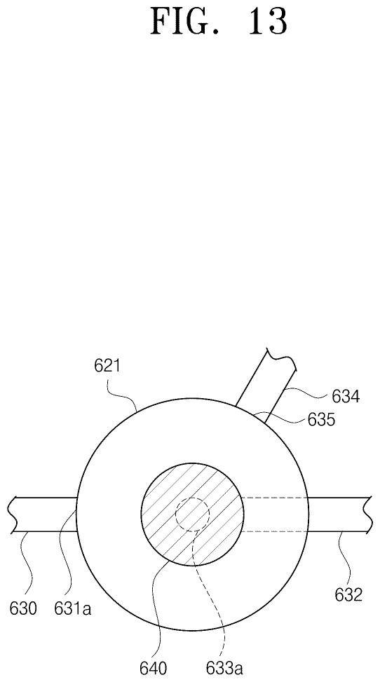

In FIG. 10, the outlet 631a of the inflow path 630, the inlet 633a of the outflow path 632, and the inlet 635 of the recirculation path 634 are sequentially provided in a straight line. However, as illustrated in FIG. 13, the outlet 631a of the inflow path 630, the inlet 633a of the outflow path 632, and the inlet 635 of the recirculation path 634 may be provided at positions away from each other in a straight line. For example, the angle between the line connecting the outlet 631a of the inflow path 630 and the inlet 633a of the outflow path 632 and the line connecting the inlet 633a of the outflow path 632 and the inlet 635 of the recirculation path 634 may be an acute angle, a right angle, or an obtuse angle.

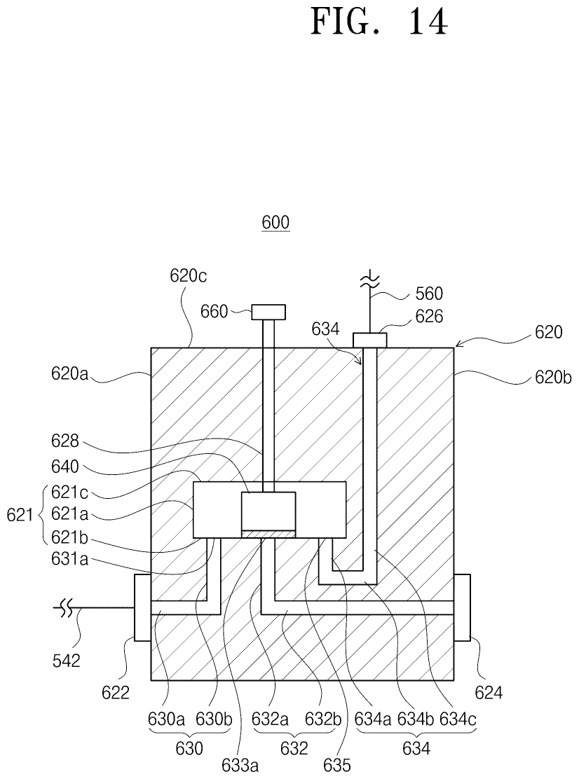

In FIG. 6, the present invention has been described that the suction space 636 is provided in the valve assembly 600. Unlike this, however, as illustrated in FIG. 14, the suction space 636 may not be provided in the valve assembly 600.

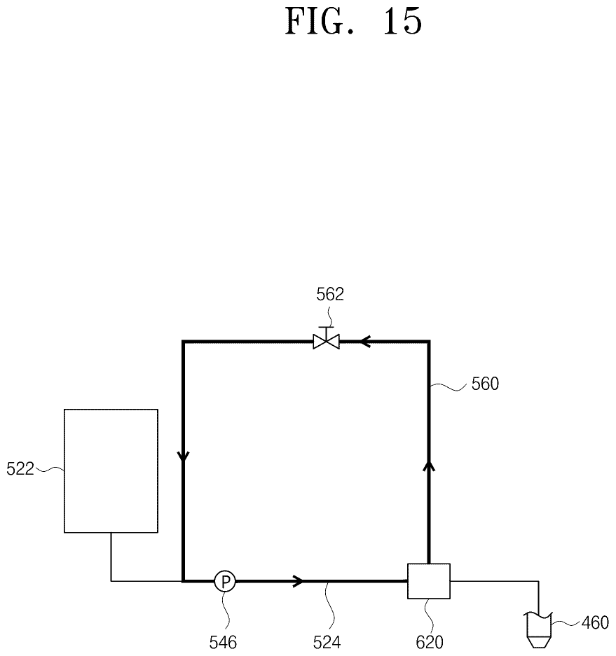

In FIG. 9, the present invention has been described that the recirculation line 560 is connected to the supply tank 522 so that the treatment liquid flowing through the recirculation port 626 of the valve assembly 600 is recovered to the supply tank 522. However, unlike this, as illustrated in FIG. 15, the recirculation line 560 is directly connected to the first line 542, and the treatment liquid flowing through the recirculation port 626 of the valve assembly 600 may flow back to the valve assembly 600 through the first line 542 without being recovered to the supply tank 522.

What is claimed is:

1. An apparatus for treating a substrate, the apparatus comprising:
a liquid treating chamber formed with a treatment space in which a treatment liquid is supplied onto a substrate to liquid-treat the substrate; and
a liquid supply unit for supplying the treatment liquid to the liquid treating chamber,
wherein the liquid supply unit includes:
a liquid supply line through which the treatment liquid flows; and
a valve assembly installed in the liquid supply line, and
the valve assembly includes:
a body including an inlet port through which the treatment liquid is introduced from a liquid supply source side, an outlet port through which the treatment liquid is discharged to the liquid treating chamber side, and a recirculation port through which the treatment liquid returns to the liquid supply source side; and
a diaphragm provided to the body and opening and closing a flow path of the treatment liquid flowing toward the outlet port side.

2. The apparatus of claim 1, wherein the body is formed with:
a buffer space;
an inflow path connecting the inlet port and the buffer space;
an outflow path connecting the buffer space and the outlet port; and
a recirculation path connecting the buffer space and the recirculation port therein.

3. The apparatus of claim 2, wherein the valve assembly further includes a driver for moving the diaphragm between an open position for opening the outflow path and a closed position for closing the outflow path, and
when the diaphragm is in the closed position, the diaphragm is located in the buffer space.

4. The apparatus of claim 3, wherein the buffer space is defined by an inner wall, a bottom wall, and an upper wall, and
when the diaphragm is in the closed position, the diaphragm is located to be spaced apart from the inner wall.

5. The apparatus of claim 4, wherein the buffer space is provided in a cylindrical shape, and
a central axis of the buffer space and a central axis of the diaphragm coincide with each other.

6. The apparatus of claim 4, wherein an inlet of the outflow path is located in the bottom wall.

7. The apparatus of claim 4, wherein an outlet of the inflow path and an inlet of the recirculation path are each located at the inner wall.

8. The apparatus of claim 7, wherein when viewed from above, the outlet of the inflow path, an inlet of the outflow path, and the inlet of the recirculation path are sequentially arranged in a straight line.

9. The apparatus of claim 4, wherein an outlet of the inflow path and an inlet of the recirculation path are located in the bottom wall.

10. The apparatus of claim 9, wherein when viewed from above, the outlet of the inflow path, an inlet of the outflow path, and the inlet of the recirculation path are sequentially arranged in a straight line.

11. The apparatus of claim 1, wherein the liquid supply source includes a supply tank in which the treatment liquid is stored,
the liquid supply line includes:
a first line connecting the liquid supply source to the inlet port of the valve assembly;
a second line connecting the outlet port of the valve assembly to the liquid treating chamber, and
the recirculation port and the supply tank are connected by a recirculation line, and an opening/closing valve is installed on the recirculation line.

12. The apparatus of claim 1, wherein the body is formed with:
a buffer space;
an inflow path connecting the inlet port and the buffer space;
an outflow path connecting the buffer space and the outlet port; and
a recirculation path connecting the inflow path and the recirculation port is formed therein.

13. The apparatus of claim 2, wherein the valve assembly is further formed with a suction space directly communicating with the outflow path, and
the valve assembly further includes a suction plate that adjusts a volume of the suction space.

14. The apparatus of claim 11, wherein the valve assembly includes a driver that moves the diaphragm between an open position that opens the outflow path and a closed position that closes the outflow path,
the apparatus further includes a controller for controlling the driver and the opening/closing valve, and
the controller controls the driver and the opening/closing valve to open the opening/closing valve when the diaphragm is in the closing position and close the opening/closing valve when the diaphragm is in the opening position.

15. A valve assembly comprising: a body including: an inlet port through which a treatment fluid is introduced from a liquid supply source side;
an outlet port through which a treatment fluid is discharged toward a liquid treating chamber side; and
a body including a recirculation port for returning the treatment liquid toward the liquid supply source side; and
a diaphragm provided to the body and opening and closing a flow path of the treatment liquid flowing toward the outlet port side.

16. The valve assembly of claim 15, wherein the body is formed with:
a buffer space defined by an inner wall, a bottom wall, and an upper wall;
an inflow path connecting the inlet port and the buffer space;
an outflow path connecting the buffer space above and the outlet port; and
a recirculation path connecting the buffer space and the recirculation port therein,
the diaphragm is provided to be movable between an open position that opens the outflow path and a closed position that closes the outflow path, and
when the diaphragm is in the closed position, the diaphragm is located in the buffer space to be spaced apart from the inner wall.

17. The valve assembly of claim 16, wherein the buffer space is defined by an inner wall, a bottom wall, and an upper wall, and
an inlet of the outflow path is located in the bottom wall of the buffer space.

18. The valve assembly of claim 17, wherein an outlet of the inflow path and an inlet of the recirculation path are located in the inner wall, and
when viewed from above, the outlet of the inflow path, the inlet of the outflow path, and the inlet of the recirculation path are sequentially arranged in a straight line.

19. The valve assembly of claim 17, wherein an outlet of the inflow path and an inlet of the recirculation path are located in the bottom wall, ands
when viewed from above, the outlet of the inflow path, the inlet of the outflow path, and the inlet of the recirculation path are sequentially arranged in a straight line.

20. An apparatus for treating a substrate, the apparatus comprising:
a liquid treating chamber having a treatment space in which a treatment liquid is supplied onto a substrate to liquid-treat the substrate; and
a liquid supply unit for supplying the treatment liquid to the liquid treating chamber,
wherein the liquid supply unit includes:
a supply tank in which the treatment liquid is stored;
a liquid supply line through which the treatment liquid in the supply tank flows into a liquid treating chamber; and
a valve assembly installed in the liquid supply line, and
the valve assembly includes:
a body including an inlet port through which the treatment fluid is introduced from a liquid supply source side, an outlet port through which the treatment liquid is discharged toward the liquid treating chamber side, and a recirculation port which returns the treatment liquid to the liquid supply source side, and a buffer space, and formed with an inflow path connecting the inlet port and the buffer space, an outflow path connecting the buffer space and the outlet port, and a recirculation path connecting the buffer space and the recirculation port;
a diaphragm located in the buffer space and opening and closing an inlet of the outflow path; and
a driver that moves the diaphragm between an open position that opens the inlet of the outflow path and a closed position that closes the inlet of the outflow path,
the buffer space is defined by an inner wall, a bottom wall, and an upper wall, and
when the diaphragm is in the closed position, the diaphragm is located in the buffer space to be spaced apart from the inner wall,
the recirculation port and the supply tank are connected by a recirculation line, and
an opening/closing valve is installed on the recirculation line.
